(19) United States
(12) Patent Application Publication
(10) Pub. No.: US 2010/0271225 A1
(43) Pub. Date: Oct. 28, 2010

(54) METHOD AND APPARATUS FOR DETECTING A FAULT IN A SUPPLY LINE

(75) Inventors: Raymond James Palmer, Callaghan (AU); Eric Muschka Schultz, Callaghan (AU); Erickson Bruce Myers, Clairemont (AU)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Aurora Energy Pty Ltd., Hobart (AU)

(21) Appl. No.: 12/310,278

(22) PCT Filed: Aug. 17, 2007
(86) PCT No.: PCT/AU2007/001165

§ 371 Date: Jun. 14, 2010

(30) Foreign Application Priority Data
Aug. 18, 2006 (AU) 2006904513
Nov. 20, 2006 (AU) 2006906468

(51) Int. Cl. G08B 21/00; G01R 31/02

(52) U.S. Cl. 340/650; 324/543

(57) ABSTRACT

A method is disclosed for detecting a discontinuity or irregularity in a supply line of an electrical power distribution network including a neutral return line and an earth return line. The method includes measuring a property associated with the supply line wherein the property is different when the network includes the neutral return line compared to when the network does not include the neutral return line. The method also includes comparing a result of the measuring with a reference to provide an indication of the discontinuity or irregularity. The property may include a complex impedance associated with the neutral return line or earth return line and/or ambient electrical noise present on the supply line. An apparatus for detecting a discontinuity or irregularity in a supply line of an electrical power distribution network is also disclosed.

### BACKGROUND OF THE INVENTION

The present invention relates to monitoring faults in electrical power supply lines. In particular the invention relates to detecting a fault such as a discontinuity or impedance irregularity in a supply line of an electrical power distribution network including utility owned and customer owned supply lines.

The electricity power supply industry in Australia and those internationally which have four wire systems rely on a multiple earthed neutral connection to provide a protected path in case of faults flow of current in the system is normally between active and neutral. The system allows current to flow between active and earth when a fault occurs in equipment connected to the system. This flow of current through a low impedance path can operate a protective device under fault conditions such as a fuse or circuit breaker so long as a circuit to neutral or earth is in place.

Because the current can flow in one of two circuits (neutral or earth), a discontinuity or impedance irregularity in one circuit can go undetected for a period of time without any indication of danger until the second circuit (earth or neutral) also becomes defective.

For example, a high impedance or discontinuity in a neutral return line may allow current to flow between active and earth. However, the earth connection may become ineffective or defective over time due to a number of factors including drying out of the soil, a faulty connection or cable damage following work carried out on plumbing or the like. When a sound earth connection is not in place current may flow to earth through other paths such as water pipes and storm drains or it may not flow at all. This may cause a rise in voltage potential above earth and may create a danger of electric shock to persons with a possibility of injury or death.

An object of the present invention is to at least alleviate the disadvantages of the status quo.

### SUMMARY OF THE INVENTION

The present invention may detect a discontinuity or impedance irregularity in a neutral return line. The present invention may detect the discontinuity or irregularity at a consumer site. The present invention may detect the discontinuity or irregularity by monitoring and/or measuring a property associated with the supply line. The property may include a complex impedance associated with the supply line and/or ambient (including naturally and/or artificially generated) electrical noise present on the supply line.

At a relatively low frequency such as 50 Hz, the impedance of an earth return line may be similar to that of a neutral return line. Hence if a neutral line is broken electricity will still flow to a good earth return line and there may be little or no effect on the voltage at a GPO (general power outlet) socket, appliance and/or equipment at a consumer site. However at higher frequencies the impedances of an earth return line and a neutral return line differ more than at 50 Hz.

Measurement of an impedance in a circuit or line is generally performed by injecting a signal into the circuit or line and measuring a change in the signal due to the impedance. However, the present invention may make use of background noise to measure impedances of return lines in the neutral and earth circuits. Background noise is inherent in most networks and is generated from a variety of sources including random switching of loads, reception from radiated sources such as radio and television transmitters as well as noise due to the physics of electron conduction.

When the neutral line is intact, the active and neutral lines along overhead transmission lines form an effective antenna loop which extends in a horizontal plane. Since a loop is more sensitive along an axis normal to the plane of the loop, the overhead lines are sensitive to electro-magnetic noise induced along a vertical axis. When the neutral line breaks, a portion of the loop close to the house extends in a vertical plane which is sensitive along a horizontal axis.

Sources of electro-magnetic signals along a vertical axis have higher components emanating from space, for example solar interference, whereas sources of signals along a horizontal axis have higher components emanating from man-made sources such as radio and television broadcasts. Hence it may be expected that the vertical and horizontal orientations will have different spectral characteristics, which may be detected by a statistical measure or measures of the electrical spectrum associated with the power distribution network.

The present invention may be adapted to exploit the abovementioned properties of an earth return line relative to a neutral return line or wire to detect a discontinuity or impedance irregularity in the neutral return line or wire. The present invention may employ various methods to detect a discontinuity or irregularity in the neutral return line including analysis of time domain, source impedance and/or frequency domain of the power distribution network.

Analysis of the electrical spectrum associated with the power distribution network may include comparing short term statistical measures including full width power spectrum distribution and/or across selected frequency bands within the power spectrum distribution to a long term moving average or averages of the full width power spectrum distribution and/or across selected frequency bands within the power spectrum distribution to identify changes that may be indicative of a discontinuity or irregularity in the neutral return line.

Analysis of the impedance associated with the power distribution network may include calculating a change or changes in a parameter or parameters which are based upon statistical measures derived from the power spectrum distribution and implied site impedances derived from the power spectrum distribution obtained under both high and low impedance conditions. The latter may be assessed in comparison to a reference or references to indicate a discontinuity or irregularity in the neutral return line.

Analysis of the electrical spectrum associated with the power distribution network may include calculating various statistical measures for the power spectrum distribution and comparing these measures with reference data to indicate a discontinuity or irregularity in the neutral return line.

The present invention includes apparatus for detecting a discontinuity or irregularity in a supply line of an electrical power distribution network. The discontinuity or irregularity may be present anywhere between a supply transformer and a point of connection of the apparatus to the power distribution network. The apparatus may be installed in a customer's premises such as at a GPO that forms a part of the network.

The apparatus may be adapted to differentiate between circuits having an intact neutral return line, and circuits having a discontinuity or irregularity in a neutral return line. Electrical properties as well as physical dimensions and characteristics associated with an electrical network having an intact neutral return line, differ from those associated with an electrical network having a discontinuity or irregularity in a neutral line or wire. These differences include alterations in impedances present in circuits associated with the electrical networks, and/or the axis of sensitivity of the circuits to induced noise from radiated electro-magnetic fields. This in turn results in variations between a power spectrum distribution of electrical noise obtained from the power distribution network with an intact neutral line or wire, and a power spectrum distribution of electrical noise obtained from the power distribution network with a discontinuity or irregularity in a neutral return line. Test results have shown clear differences in:
shape of the spectra
statistical measures associated with the signal

The above differences may allow the apparatus to differentiate between a power distribution network with an intact neutral line or wire and a power distribution network with a discontinuity or irregularity in a neutral line or wire.

In one form the apparatus may include means for measuring voltage between an active and neutral line associated with a power outlet. The apparatus may include means for applying an electrical load to a main voltage supply. The apparatus may include means for switching a load between a relatively high impedance, and a relatively low impedance. Switching of the load may be under control of a microprocessor.

The apparatus may also include means for limiting spectral content of the mains voltage signal. The limiting means may include a band pass filter filtering of the mains voltage signal may reduce the 50 Hz component of the mains voltage signal to an insignificant value. It may also eliminate spectral content of the signal above the Nyquist frequency criterion to facilitate subsequent sampling of the signal.

The level of uncorrelated noise that is present on the mains signal may be measured by converting the analog signal to a digital representation by means of an analog to digital converter (A to D). The analog to digital conversion may provide discrete sampled levels of the filtered input.

The Fourier transform may be calculated by means of a Fast Fourier Transform (FFT) analyser. The FFT analyser may include a digital processing unit. The FFT is based on conversion of a time domain waveform to the frequency domain. The FFT analyser may calculate the spectrum of the noise over a range of frequencies.

Because the input signal may include a strong local noise source that is not random, the apparatus may include means for removing correlated signals.

Because a discontinuity or impedance irregularity in a neutral return line may change the path of return current flow and local earth impedance may be different than the impedance of a neutral return line, this may result in a voltage' difference between the active and neutral lines of a local network. Hence the existence of the discontinuity or irregularity may be detected or at least confirmed by measuring a change in voltage between the active and neutral lines. This feature may be used in some embodiments to supplement a measurement or result obtained by means of one or more of the embodiments described above.

As loads are naturally switched in and out of a local network circuit they may produce step changes in impedance of the local network. A step change in the voltage between the active and neutral lines in a local network may follow the step change in impedance. A voltage or step change in voltage measured between the active and neutral lines resulting from the natural switching of loads in a local network may be compared instantaneously and/or over time to a reference voltage to provide an indication or a confirmation of a discontinuity or impedance irregularity in a neutral return line.

The apparatus may include means such as an audible or visual signal or an alarm to communicate to the consumer and/or a third party that a neutral return line or wire may contain a discontinuity or irregularity.

According to one aspect of the present invention there is provided a method for detecting a discontinuity or irregularity in a supply line of an electrical power distribution network including a neutral return line and an earth return line, said method including:
measuring a property associated with said supply line wherein said property is different when said network includes said neutral return line compared to when said network does not include said neutral return line; and
comparing a result of said measuring with a reference to provide an indication of said discontinuity or irregularity.

According to a further aspect of the present invention there is provided an apparatus for detecting a discontinuity or irregularity in a supply line of an electrical power distribution network including a neutral return line and an earth return line, said apparatus including:
means for measuring a property associated with said supply line, wherein said property is different when said network includes said neutral return line compared to when said network does not include said neutral return line; and
means for comparing a result of said measuring with a reference to provide an indication of said discontinuity or irregularity.

In one form the property may include a complex impedance associated with the neutral return line and/or earth return line of the electrical power distribution network. In another form the property may include ambient electrical noise present on the supply line of the network.

Preferred embodiments of the present invention will now be described with reference to the accompanying drawings wherein:

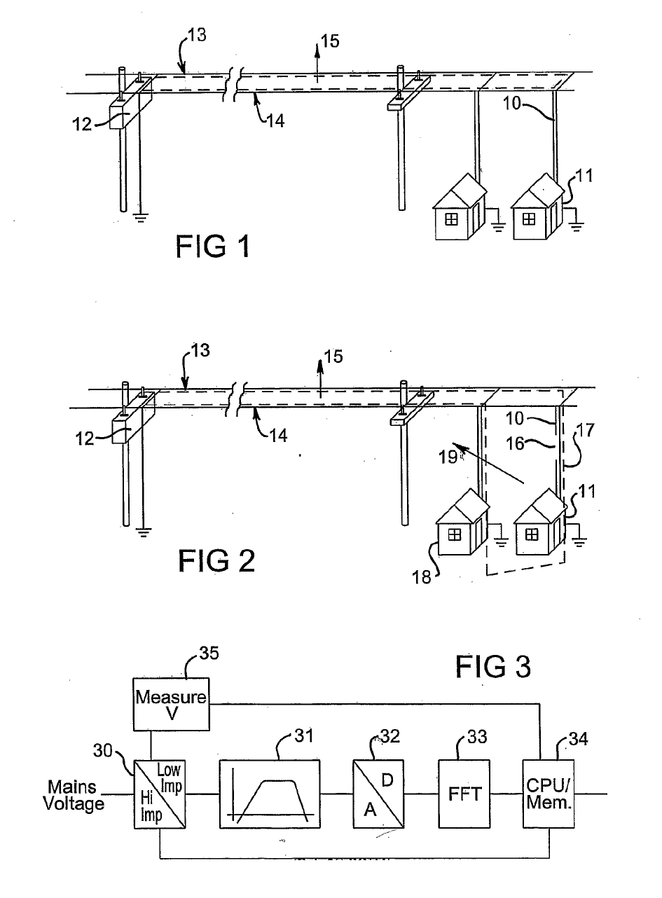

FIG. 1 shows a simplified diagram of a typical installation;

FIG. 2 shows a simplified diagram of a faulty installation;

FIG. 3 shows a block diagram of an apparatus for detecting a discontinuity in an electrical power distribution system;

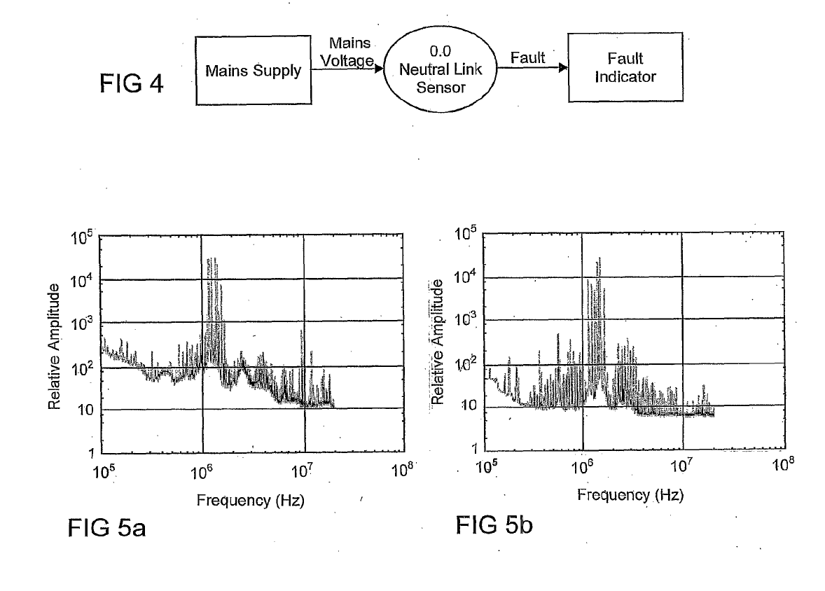

FIG. 4 shows a context of operation for a neutral line sensor;

FIGS. 5a and 5b show an average of measured spectra for 250 sample sets for broken and intact neutral lines respectively;

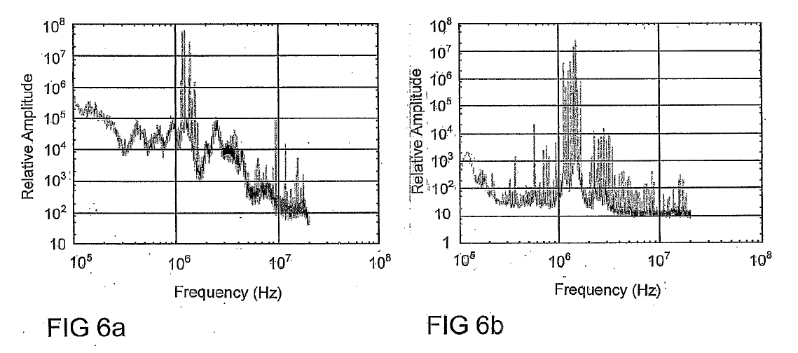

FIGS. 6a and 6b show a variance of measured spectra for 250 sample sets for broken and intact neutral lines respectively;

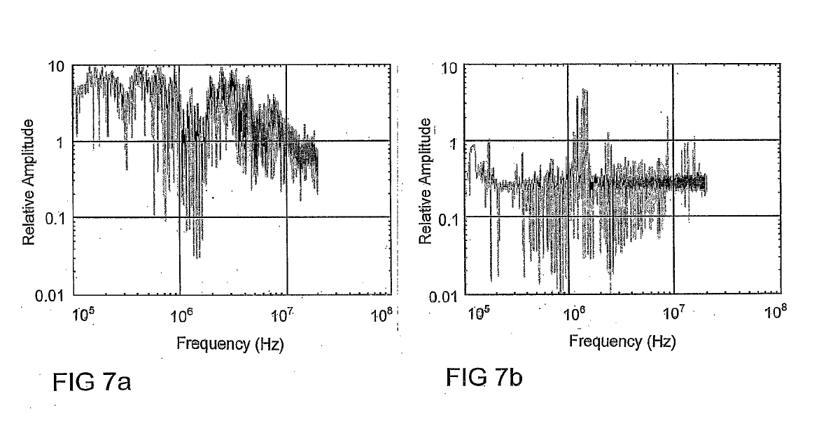

FIGS. 7a and 7b show a variance divided by a mean squared of measured spectra for 250 sample sets for broken and intact neutral lines respectively;

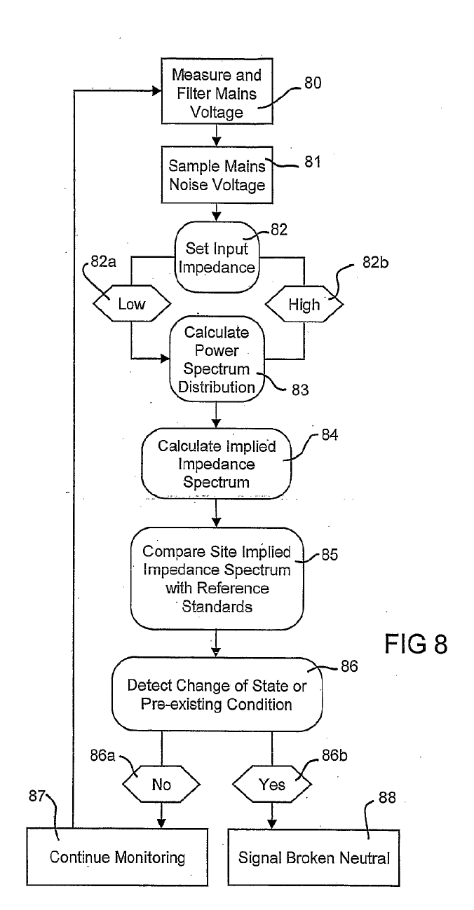

FIG. 8 shows a flow chart associated with analysis of source impedance;

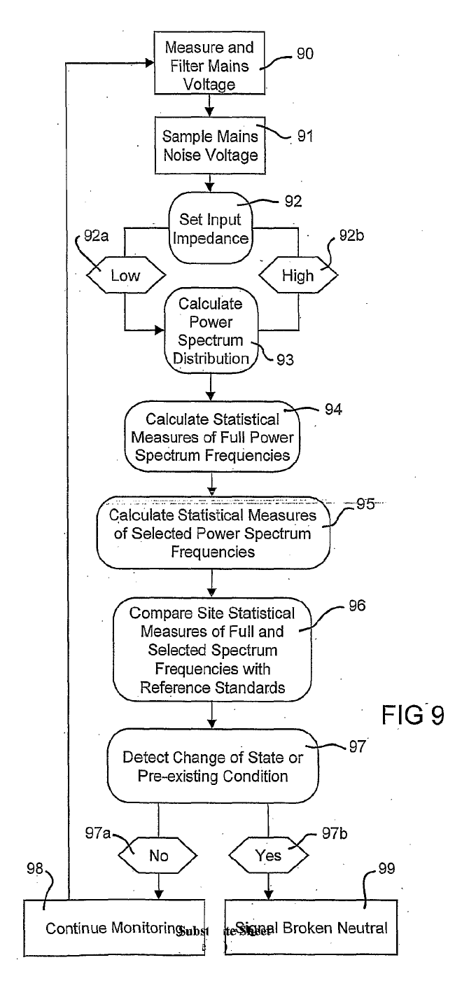

FIG. 9 shows a flow chart associated with analysis of frequency domain;

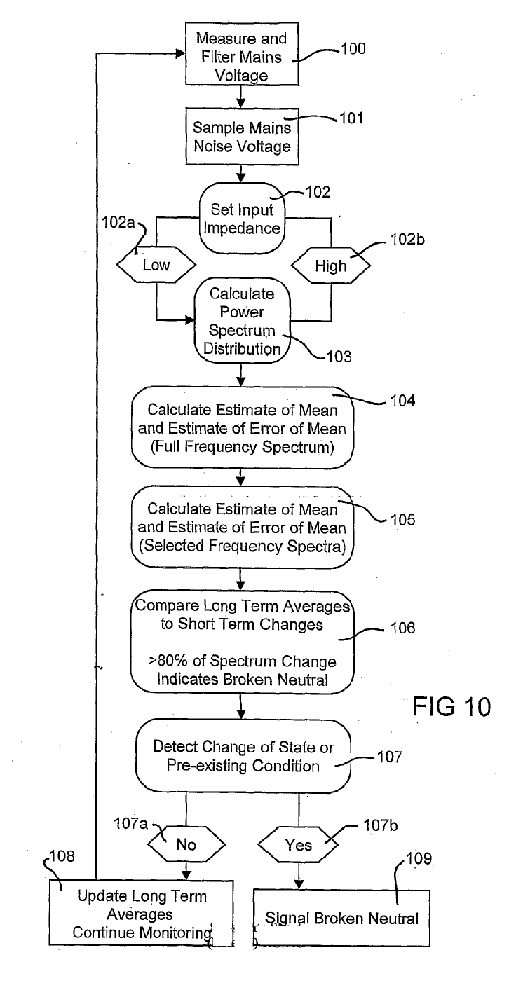

FIG. 10 shows a flow chart associated with analysis of time domain;

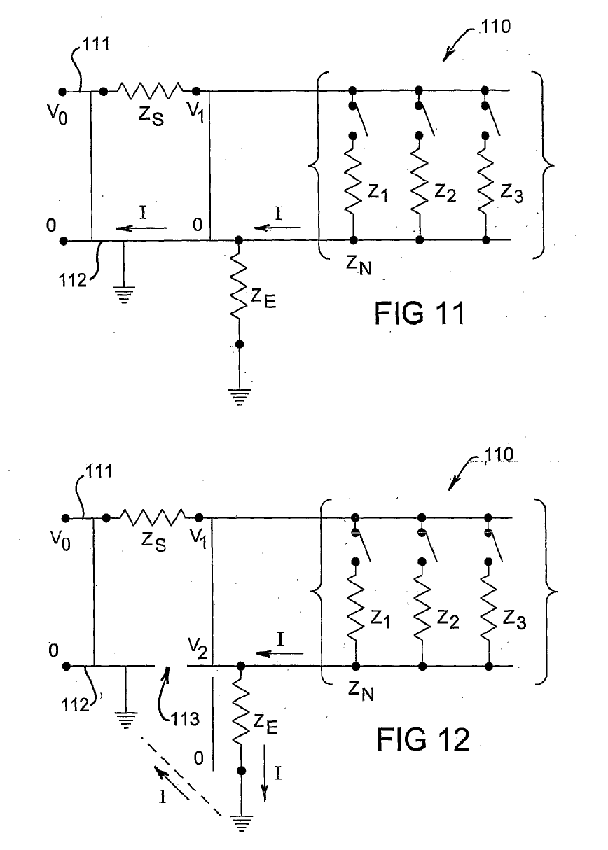

FIG. 11 shows a representation of a local network including an intact neutral return line; and

FIG. 12 shows a representation of a local network including a discontinuous neutral return line.

Referring to FIG. 1 there is shown a simplified example of a domestic electrical power supply installation having an intact neutral return line 10 between house 11 and distribution transformer 12. Overhead transmission line 13 between house 11 and distribution transformer 12 forms a primary loop 14 that can have voltages induced by ambient electromagnetic (EM) fields linking with loop 14.

Primary loop 14 is typically oriented substantially in a horizontal plane hence it has a sensitive axis 15 that extends substantially vertically as shown in FIG. 1. This implies that primary loop 14 is more sensitive to EM sources that are located directly above primary loop 14.

FIG. 2 shows the same domestic power supply installation including a break 16 in the neutral return line 10 to house 11. In this case the earth and the water-pipe bond form a secondary loop 17 with the neutral connection of house 18 next door and/or with an earth return connection of distribution transformer 12. One effect of the broken neutral return line 10 is that it modifies the physical dimensions and orientation of loop 14 to include the secondary loop 17. Secondary loop 17 is oriented substantially in a vertical plane hence it has a sensitive axis 19 that extends substantially horizontally as shown in FIG. 2. Hence the loop formed by a discontinuity or irregularity in the neutral line or wire will be more sensitive to EM sources that are located on the same horizontal plane, such as most radio and television transmitters.

Radio and television transmitters carry information that has a statistical profile which is different to the random switching of loads. Hence increased sensitivity when a neutral line becomes discontinuous, should change the statistical profile of the measured noise.

Another effect of the change in the dimensions of the loop is that the characteristic impedance of the transmission line will change due to the change in dimensions.

A further effect of the loss of the neutral line is that the return current has to flow through a path in the earth. This path includes an impedance that changes with frequency. The change in impedance occurs because at lower frequencies, the current is conducted by ions in the soil. At higher frequencies the ions do not respond fast enough to the applied electric field, and the impedance changes.

FIG. 3 shows a block diagram of one form of apparatus for detecting a discontinuity or impedance irregularity in an electrical power distribution system. The apparatus includes load block 30 for applying an electrical load to a main voltage supply. Load block 30 includes means for switching between a relatively high impedance and a relatively low impedance. Load block 30 may be switched between the high and low impedances under control of a microprocessor.

The apparatus includes band pass filter block 31 for filtering the mains input voltage. Filter block 31 is adapted to reduce the 50 Hz mains voltage to an insignificant value and to eliminate frequency content above the Nyquist frequency criterion. The latter may avoid aliasing of higher frequency signals to facilitate accurate sampling by A to D converter 32.

Band pass filter block 31 may pass signals within a frequency range. A to D converter 32 is adapted to convert the analog input signal to a digital representation. The A to D conversion provides discrete sampled levels of the filtered input which allows a Fourier transform to be calculated in FFT block 33. FFT block 33 may include a hardware or software implementation of a Fast Fourier transform. FFT block 33 calculates the spectrum of the noise over a range of frequencies selected by filter block 31.

The apparatus includes a microprocessor/memory block 34 for determining whether transmission of the noise occurred through a power distribution network with an intact neutral line or wire or a power distribution network with a discontinuity or irregularity in a neutral line or wire. The transformed data is stored in the memory and pre-processed by the microprocessor to decide whether a fault condition has occurred.

The apparatus includes voltage measurement block 35. Voltage measurement block 35 provides a measurement of actual mains voltage as an input to microprocessor/memory block 34 for use in determining and/or confirming whether the power distribution system has a discontinuity or irregularity in a neutral line or wire.

FIG. 4 shows the context of operation for a neutral link (discontinuity or irregularity) sensor. Graphs of variance (refer FIG. 6) display a clear difference between a broken neutral and an intact neutral case. In the example shown the baseline of a broken neutral graph (FIG. 6a) has a relatively constant negative slope from 100 kHz to 20 MHz, while the baseline of variance for an intact neutral case (FIG. 6b) declines from 100 kHz approximately 500 kHz, and then remains approximately flat to 20 MHz. Other examples may have different characteristics that distinguish the intact and broken case.

Calculations of statistical measures show a strong indication of presence of a discontinuity or irregularity in a neutral line or wire. In a broken neutral case, variance of the signal is different to an intact neutral case.

Referring to FIG. 8 analysis of source impedance includes the steps of measuring and filtering the mains voltage (80) and sampling the mains noise voltage (81). The analysis includes setting an input impedance low (82a) and then high (82b) and calculating distribution of its power spectrum (83). The analysis includes calculating an implied impedance spectrum for a given site (84) and comparing the implied impedance spectrum for the site with a reference (85). The result of the comparison may detect a change of state or pre-existing condition (86). If no change of state or pre-existing condition is detected (86a) the analysis may continue monitoring (87). If a change of state or pre-existing condition is detected (86b) it is likely that it indicates a broken neutral line (88).

Referring to FIG. 9 analysis of frequency domain includes the steps of measuring and filtering the mains voltage (90) and sampling the mains noise voltage (91). The analysis includes setting an input impedance low (92a) and then high (92b) and calculating distribution of its power spectrum (93). The analysis includes calculating statistical measures of full power spectrum frequencies (94) and calculating statistical measures of selected power spectrum frequencies (95) for a given site. The analysis includes comparing the site statistical measures of full and selected spectrum frequencies with a stored reference (96). The result of the comparison may detect a change of state or pre-existing condition (97). If no change of state or pre-existing condition is detected (97a) the analysis may continue monitoring (98). If a change of state ore pre-existing condition is detected (97b) it is likely that it indicates a broken neutral line (99).

Referring to FIG. 10 analysis of time domain includes the steps of measuring and filtering the mains voltage (100) and sampling the mains noise voltage (101). The analysis includes setting an input impedance low (102a) and then high (102b) and calculating distribution of its power spectrum (103). For both low and high impedance measurements, the analysis includes calculating an estimate of mean and an estimate of error of mean for a full frequency spectrum (104). The analysis also includes calculating an estimate of mean and an estimate of error of mean for selected frequency spectra (105). The analysis includes comparing long term averages to short term changes such that a significant spectrum change (eg. more than 80%) may be taken to indicate a broken neutral line (106). The result of the comparison may detect a change of state or pre-existing condition (107). If no change of state or pre-existing condition is detected (107a), the analysis may update long term averages and continue monitoring (108). If a change of state or pre-existing condition is detected (107b), it is likely that it indicates a broken neutral line (109).

FIG. 11 shows a representation of a local network 110 including a plurality of naturally switched loads Z₁, Z₂, Z₃ connected between active line 111 and neutral return line 112. A local current I flows between the active neutral lines determined by voltage V₁ across the local network and total local network impedance Z_{N}. Assuming that the neutral line 112 is intact the voltage V₁ measured across the local network equals the active supply voltage Vₒ. Source impedance associated with active line 111 is represented by Z_{N} while local earth impedance is represented by Z_{E}. Local current I does not flow via impedance Z_{E} so long as neutral return line 112 remains intact.

FIG. 12 shows the local network 110 of FIG. 11 including a discontinuity 113 in neutral return line 112. Discontinuity 113 may give rise to a change in source impedance Z_{S} although the change may not be significant. The local current I now flows via earth impedance Z_{E} causing voltage V₂ to rise above the neutral line voltage such that

$${V}_{2} = {V}_{o} ( \frac{{Z}_{E}}{{Z}_{E} + {Z}_{N} + {Z}_{S}} )$$

This causes a drop in voltage V₁ across the local network such that

$$\begin{matrix}{V}_{1} = {V}_{o} - {V}_{2} \\ = {V}_{o} - {V}_{o} ( \frac{{Z}_{E}}{{Z}_{E} + {Z}_{N} + {Z}_{S}} ) \\ = {V}_{o} ( \frac{{Z}_{N} + {Z}_{S}}{{Z}_{E} + {Z}_{N} + {Z}_{S}} )\end{matrix}$$

Therefore in the event of discontinuity 113 in the return neutral line 112, the voltage V₁ across the local network 110 is less than the line voltage Vₒ since (Z_{N}+Z_{S})/(Z_{E}+Z_{N}+Z_{S}) is less than 1. This drop in local voltage V₁ may be detected by comparing V₁ to a reference or standard voltage to provide an indication of the discontinuity or an impedance irregularity in neutral return line 112.

Finally, it is to be understood that various alterations, modifications and/or additions may be introduced into the constructions and arrangements of parts previously described without departing from the spirit or ambit of the invention.

1. A method for detecting a discontinuity or irregularity in a supply line of an electrical power distribution network including a neutral return line and an earth return line, said method including:
measuring a property associated with said supply line wherein said property is different when said network includes said neutral return line compared to when said network does not include said neutral return line; and
comparing a result of said measuring with a reference to provide an indication of said discontinuity or irregularity.

2. A method according to claim 1 wherein said property includes a complex impedance associated with said neutral return line.

3. A method according to claim 1 or 2 wherein said reference is selected to discriminate a network that includes said neutral return line from a network that does not include said neutral return line.

4. A method according to claim 2 or 3 including measuring a voltage between said neutral return line and an active line and comparing said measured voltage and/or step changes in voltage instantaneously and/or over time to a reference voltage.

5. A method according to any one of the preceding claims wherein said property includes ambient electrical noise present on said supply line.

6. A method according to any one of the preceding claims wherein said reference includes data samples obtained from a plurality of sites when said network does not include said neutral return line.

7. A method according to any one of the preceding claims wherein said reference includes data samples obtained from a plurality of sites when said network includes said neutral return line.

8. A method according to any one of the preceding claims wherein said measuring includes performing a Fourier transform of a signal on said supply line.

9. A method according to claim 8 wherein said signal includes electrical noise.

10. A method according to claim 8 or 9 including limiting bandwidth of said signal.

11. A method according to claim 8, 9 or 10 including removing from said signal noise which is not random.

12. A method according to any one of the preceding claims wherein said indication includes an audible and/or visual alarm and/or an electrical signal.

13. Apparatus for detecting a discontinuity or irregularity in a supply line of an electrical power distribution network including a neutral return line and an earth return line, said apparatus including:
means for measuring a property associated with said supply line, wherein said property is different when said network includes said neutral return line compared to when said network does not include said neutral return line; and
means for comparing a result of said measuring with a reference to provide an indication of said discontinuity or irregularity.

14. Apparatus according to claim 13 wherein said property includes a complex impedance associated with said neutral return line.

15. Apparatus according to claim 13 or 14 wherein said reference is selected to discriminate a network that includes said neutral return line from a network that does not include said neutral return line.

16. Apparatus according to claim 14 or 15 including means for measuring a voltage between said neutral return line and an active line and means for comparing said measured voltage and/or step changes in voltage instantaneously and/or over time to a reference voltage.

17. Apparatus according to any one of claims 13 to 16 wherein said property includes ambient electrical noise present on said supply line.

18. Apparatus according to any one of claims 13 to 17 wherein said reference includes data samples obtained from a plurality of sites when said network does not include said neutral return line.

19. Apparatus according to any one of claims 13 to 18 wherein said reference includes data samples obtained from a plurality of sites when said network includes said neutral return line.

20. Apparatus according to any one of claims 13 to 19 wherein said measuring means includes a bandpass filter.

21. Apparatus according to any one of claims 13 to 20 wherein said measuring means includes an analog to digital converter.

22. Apparatus according to any one of claims 13 to 21 wherein said measuring means includes a fast Fourier transform analyser.

23. Apparatus according to any one of claims 13 to 22 wherein said supply line contains electrical noise.

24. Apparatus according to any one of claims 13 to 23 wherein said comparing means includes a central processing unit and a memory for storing data associated with said reference.

25. Apparatus according to any one of claims 13 to 24 wherein said indication includes an audible and/or visual alarm and/or an electrical signal.

26. A method for detecting a discontinuity or irregularity in a supply line of an electrical power distribution network substantially as herein described with reference to the accompanying drawings.

27. Apparatus for detecting a discontinuity or irregularity in a supply line of an electrical power distribution network substantially as herein described with reference to the accompanying drawings.
